(19) United States
(12) Patent Application Publication
(10) Pub. No.: US 2025/0392875 A1
(43) Pub. Date: Dec. 25, 2025

(54) HEARING DEVICE AND METHOD FOR OPERATING A HEARING DEVICE

(71) Applicant: Sivantos Pte. Ltd., Singapore (SG)

(72) Inventors: Jurek FÖLLMER, Erlangen (DE); Cecil WILSON, Erlangen (DE); Sebastian BEST, Erlangen (DE)

(21) Appl. No.: 19/317,388

(22) Filed: Sep. 3, 2025

Related U.S. Application Data
(63) Continuation of application No. PCT/EP2024/064022, filed on May 22, 2024.

(30) Foreign Application Priority Data
May 23, 2023 (DE) 10 2023 204 769.1

(51) Int. Cl. H04R 25/00

(52) U.S. Cl. CPC H04R 25/505

(57) ABSTRACT

A method operates a hearing aid which is allocated to a user. The hearing aid receives an audio signal and generates an input signal. From the input signal an automatic gain control (AGC) input signal is generated and is supplied to an AGC unit of the hearing aid. The AGC unit amplifies the AGC input signal depending on a level of the AGC input signal and in accordance with an AGC function and then outputs it as an AGC output signal. The AGC function is defined by one or more parameters which are set depending on an acoustic scene which is currently present. The hearing aid generates, from the AGC output signal, an output signal for output to the user. A hearing device is programmed to perform the method.

### CROSS-REFERENCE TO RELATED APPLICATION

This application is a continuation, under 35 U.S.C. § 120, of copending International Patent Application PCT/EP2024/064022, filed May 22, 2024, which designated the United States; this application also claims the priority, under 35 U.S.C. § 119, of German Patent Application DE 10 2023 204 769.1, filed May 23, 2023; the prior applications are herewith incorporated by reference in their entireties.

### FIELD AND BACKGROUND OF THE INVENTION

The invention relates to a hearing device and to a method for operating same.

A hearing device such as a hearing aid generally has an input transducer, a signal processor and an output transducer. The input transducer is usually a microphone. The output transducer is usually an earpiece, which is also referred to as a loudspeaker or receiver. A hearing aid is often assigned to an individual user and is used only by the user. A hearing aid is used for example to supply a user who is hard of hearing and to compensate for hearing loss of this user. The input transducer generates an input signal, which is supplied to the signal processor. The signal processor modifies the input signal and thereby generates an output signal, which is thus a modified input signal. In order to compensate for hearing loss, the input signal is amplified by a frequency-dependent gain factor, for example in accordance with an audiogram (hearing range) of the user. Finally, the output signal is output to the user by way of the output transducer. In the case of a hearing aid having a microphone and earpiece, the microphone accordingly generates the input signal from sound signals in the environment and the earpiece in turn generates a sound signal from the output signal. The input signal and the output signal are electrical signals, which are therefore also each referred to as a signal for short. The sound signals from the environment and any sound signal output by the earpiece, on the other hand, are acoustic signals.

Aside from this, it is advantageous to integrate automatic gain control (AGC) into a hearing aid. To this end, the hearing aid expediently has a corresponding AGC unit that may be used to modify the dynamic range of the input signal in order to obtain a certain dynamic range for the output signal. In this case, a level of the input signal is amplified to a level for the output signal in accordance with an AGC function. The AGC function contains for example a knee point, below which the output signal corresponds to the input signal (gain=1) and above which compression takes place (gain<1). The AGC function is also referred to as a dynamic curve.

One disadvantage of AGC is that the compression may lead to the SNR (signal-to-noise ratio) of the input signal being reduced in some situations. Especially in the case of an input signal that contains voice, voice intelligibility is thereby reduced. This is particularly problematic in a loud environment that already has a low SNR per se.

### SUMMARY OF THE INVENTION

Against this background, one object of the invention is to improve the operation of a hearing aid having an AGC unit. A correspondingly improved method and a correspondingly improved hearing aid are intended to be specified for this purpose.

The object is achieved according to the invention by a method having the features as claimed in the independent method claim and by a hearing aid having the features as claimed in the independent hearing device claim. Advantageous embodiments, developments and variants are the subject matter of the dependent claims. The explanations in connection with the method also apply analogously to the hearing aid and vice versa. Where steps of the method are described implicitly or explicitly below, these give rise to advantageous embodiments for the hearing aid in that the hearing aid has a signal processor that is configured to carry out one or more of these steps.

With the foregoing and other objects in view there is provided, in accordance with the invention, a method for operating a hearing aid being assigned to a user. The method includes: recording an audio signal via the hearing aid; generating an input signal from the audio signal; generating an automatic gain control (AGC) input signal from the input signal and supplying the AGC input signal to an AGC unit of the hearing aid; and amplifying, via the AGC unit, the AGC input signal depending on a level of the AGC input signal and in accordance with an AGC function and then outputting an amplified AGC input signal as an AGC output signal. The AGC function is defined by at least one parameter that is set in dependence on an acoustic scene that is currently present. An output signal for outputting to the user is generated in the hearing aid and is derived from the AGC output signal.

A core concept of the invention is in particular that of determining an AGC function, in accordance with which an AGC unit of a hearing aid implements AGC, in each case in optimum fashion for different acoustic scenes, and in the process also taking into consideration an individual hearing range of a user of the hearing aid. During operation of the hearing aid, the AGC function is thus advantageously adapted automatically when the scene changes, and the hearing range of the user is utilized as optimally as possible.

The method according to the invention is used to operate a hearing aid. The hearing aid is assigned to a user. In particular, the hearing aid is assigned to only one individual user and is used only by the user. Preferably, the hearing aid is used to supply a user who is hard of hearing and to compensate for hearing loss of this user, this also being assumed hereinafter without restricting generality. During operation, the user wears and uses the hearing aid, preferably on their head and in or on their ear.

The hearing aid generally has an input transducer, an output transducer and a signal processor (also referred to as signal processing unit). In one expedient embodiment, the input transducer is a microphone and the output transducer is an earpiece. Such an embodiment is assumed below without restricting generality. During operation, the input transducer generates an input signal that is supplied to the signal processor. Also during operation, the signal processor modifies the input signal and thereby ultimately generates an output signal. In order to modify the input signal, the signal processor has one or more units, which may be connected in series and/or in parallel with one another as required. In order to compensate for hearing loss, the input signal or a signal derived therefrom is amplified by a frequency-dependent gain factor, for example in accordance with an audiogram (hearing range) of the user. For this purpose, the signal processor appropriately has a corresponding amplification unit. Finally, the output signal is output to the user during operation by way of the output transducer. In the case of a hearing aid having a microphone and an earpiece, the microphone accordingly generates the input signal from sound signals in the environment and the earpiece in turn generates a sound signal from the output signal. The input signal and the output signal are electrical signals, which are therefore also each referred to as a signal for short. The sound signals from the environment and any sound signal output by the earpiece, on the other hand, are acoustic signals. As an alternative or in addition to sound signals, the hearing aid receives data signals, for example an audio stream. Any signals (sound signals, data signals) that the hearing aid receives in order to modify an output to the user are referred to collectively as audio signals.

In the method described here, the hearing aid records an audio signal, in particular by way of the input transducer, and generates an input signal therefrom, likewise by way of the input transducer. An AGC input signal is generated from the input signal and is supplied to an AGC unit of the hearing aid. In the simplest embodiment, the AGC input signal is identical to the input signal, that is to say it is simply forwarded directly to the AGC unit. Such an embodiment will be assumed below without restricting generality. As an alternative, only part of the input signal is used as AGC input signal or the input signal is also modified beforehand by another unit of the signal processor and then used as AGC input signal. The AGC unit is in particular part of the signal processor and is preferably arranged upstream of, downstream of or in parallel with the amplification unit.

The AGC unit amplifies the AGC input signal depending on a level of the AGC input signal and in accordance with an AGC function and then outputs the correspondingly amplified AGC input signal as an AGC output signal. For this purpose, the AGC function assigns a level value of the AGC output signal to each level value of the AGC input signal. The ratio between the two level values at a point of the AGC function gives rise to a gain (that is to say a gain factor) that is applied by the AGC unit for a corresponding level value of the AGC input signal in order to amplify it. The gain may in principle be less than, greater than or equal to 1, that is to say an attenuation (<1), simple forwarding (=1) or actual amplification in the stricter sense (>1) may take place. Instead of the level of the AGC input signal and AGC output signal, in an equivalent embodiment, the AGC function links the levels of the input signal and output signal. In brief: the AGC input signal (and generally the input signal) has an input dynamic range and the AGC output signal (and generally the output signal) has an output dynamic range, and the AGC function maps the input dynamic range onto the output dynamic range. The input dynamic range and the output dynamic range are also generally each referred to as a dynamic range.

The AGC function is defined by one or more parameters. In the present case, without restricting generality, multiple parameters will be assumed. The parameters define the form or the profile of the AGC function and are also referred to as AGC parameters. These parameters are advantageously settable in order to change the AGC function and thus the modification of the AGC input signal by the AGC unit. In the present case, the parameters are set depending on an acoustic scene that is currently present, that is to say depending on a current acoustic scene. More precisely: depending on the current acoustic scene, appropriate values for the parameters are selected accordingly. The AGC function is thus parameterized in each case in optimum fashion depending on the current acoustic scene. An acoustic scene (or just “scene” for short) is generally understood to mean an acoustic environment in which the user is located. The current acoustic scene is then the acoustic environment in which the user and thus also the hearing aid are actually located at the present time. The acoustic environment and thus also the scene is defined in particular by any sound signals, both useful noise and interfering noise, which may reach the user and the hearing aid with a different intensity and/or from different directions, and also by any acoustic properties of the environment, such as for example reverberation time, number of speakers, SNR (signal-to-noise ratio), etc. Examples of scenes are “conversation”, “music”, “conversation with background noise”, “interfering noise”. Other examples of scenes are situations with a certain noise level, a certain SNR or a certain dynamic range, in particular as explained in more detail below.

The acoustic scene that is currently present is expediently determined by way of a scene recognition unit of the hearing aid. The scene recognition unit is in particular part of the signal processor. The input signal or a signal derived therefrom is expediently supplied to the scene recognition unit, which then determines the scene on the basis thereof. For this purpose, the scene recognition unit contains for example a classifier. The AGC unit is in particular connected to the scene recognition unit and is controlled thereby, that is to say the parameters are set in particular automatically depending on the determination of the current acoustic scene. The scene recognition unit in particular outputs a control signal that depends on the respective scene and is received by the AGC unit, in order then to set the parameters on a scene-dependent basis. A setting speed for the parameters preferably corresponds to a speed at which the scene is determined. Optionally, the setting of the parameters is smoothed in order to optimize, for example reduce, the response to a change of scene. By way of example, the control signal is smoothed for this purpose.

Finally, the hearing aid generates an output signal to be output to the user from the AGC output signal (as already described above). The above explanations regarding the input signal apply accordingly, that is to say, in the simplest embodiment, the output signal is identical to the AGC output signal, that is to say it is simply forwarded directly to the earpiece, for example. As an alternative, only part of the AGC output signal is used as output signal, or the AGC output signal is also modified beforehand by another unit of the signal processor, for example the amplification unit, and then used as output signal.

It will be assumed below without restricting generality that the AGC input signal corresponds to the input signal and the AGC output signal corresponds to the output signal. Regardless of this, all explanations regarding the input signal and the output signal also apply analogously to the AGC input signal, respectively the AGC output signal, and vice versa.

One important advantage of the invention is in particular that the output dynamic range is controlled more accurately for different scenes. It is conceivable in principle for an AGC unit to use a fixedly specified AGC function in combination with settable time constants or, for certain predefined scenes, to adapt a threshold value above which compression takes place for the input signal. However, the invention described here goes further and deals with different scenes with an AGC function that may be parameterized differently depending on the scene by virtue of the parameters being set appropriately on a scene-dependent basis, so as to result in a correspondingly optimized AGC function for each scene. Hearing comfort and voice intelligibility are thereby improved for the user.

A further advantage is in particular that, within the same scene, the AGC carried out by the AGC unit is more stable, wherein “stable” is understood to mean that the AGC function, in a given scene dynamic range, is simply linear within this dynamic range. It is possible in principle to specify an AGC function that is stable within a specific value range with a fixed size. If the scene dynamic range goes beyond this value range, the range is simply shifted in order to encompass the dynamic range. If the dynamic range is then greater than the value range, however, this leads to the value range repeatedly shifting back and forth, which is disadvantageous. Adapting the time constants of the AGC unit may also lead to uncontrollable and/or unstable behavior. The invention described here, by contrast, changes the AGC function and thus the behavior of the AGC unit in particular only when the scene also changes, that is to say when a change of the current acoustic scene is recognized using the scene recognition unit. On the other hand, the same AGC function is used continuously within the same scene, but said AGC function is optimized for the scene by virtue of the scene-dependent setting of the parameters.

A further advantage is in particular that an SNR of the scene is at least maintained or even increased. Voice intelligibility is thereby in particular improved. In principle, a compression carried out by the AGC unit (that is to say gradient of the dynamic curve<1) leads to a reduction in SNR. In particular in loud scenes with a low SNR, this is problematic and may worsen voice intelligibility. According to the invention, in this case, the AGC function is adapted to the scene by setting the parameters depending on the current acoustic scene. This may even lead to an expansion (gradient of the dynamic curve>1), in which case the SNR of the current acoustic scene is then increased accordingly, whereas however the dynamic range of the output signal is still adapted in optimum fashion to the user, that is to say to their hearing range.

The term “dynamic range” signifies a metric for a value range covered by a changeable level of a signal (for example input signal, output signal, AGC input signal, AGC output signal). The dynamic range is defined in particular for a specified time interval, for example a time interval of 1 s. The term “lower end” is then understood to mean a minimum of the dynamic range, and in the same way the term “upper end” is understood to mean a maximum. The input dynamic range is accordingly characterized by a minimum and maximum of the AGC input signal or generally of the input signal, and in the same way the output dynamic range is characterized by a minimum and maximum of the AGC output signal or generally of the output signal. Whereas the input dynamic range is specified by the current scene, the output dynamic range is basically able to be adapted by way of the AGC function, this advantageously also being utilized here. It is additionally advantageously possible to specify a particularly suitable minimum or maximum or both for the output dynamic range, namely by parameterizing the AGC function appropriately. In one preferred embodiment, this is used to reduce or avoid a comb filter effect, as will be explained in more detail below.

In one particularly simple embodiment, the lower and upper end of the dynamic range correspond to a minimum, respectively a maximum, of the level of the signal in question, in particular within a predefined time range. Accordingly, the lower and upper end of the dynamic range of the current acoustic scene are then expediently ascertained as a minimum and maximum of the input signal within a predefined time range. Aside from the use of a minimum and maximum of the level of a signal as an upper and lower end of a dynamic range, however, other definitions are also suitable, in particular based on a statistical analysis. By way of example, the upper and lower end correspond to a degree of scatter (for example standard deviation) of the level values starting from a measure of central tendency (for example median) of the level values, in particular within a predefined time interval. In one suitable embodiment, the lower and upper end of the dynamic range of the current acoustic scene are accordingly ascertained based on a statistical analysis of the input signal.

Advantageously, the dynamic range of the current acoustic scene is ascertained with a lower end and an upper end. In other words: the current acoustic scene has a dynamic range that is ascertained, for example derived from the input signal, for example either directly as a minimum and maximum of the input signal or as a minimum and maximum of the AGC input signal, which is for its part derived from the input signal. The dynamic range of the current acoustic scene is also referred to as the scene dynamic range. The input dynamic range already mentioned or a dynamic range derived therefrom is particularly suitable as a dynamic range of the current acoustic scene. The ascertaining of the scene dynamic range is expediently part of the method described here. In one suitable embodiment, the scene dynamic range is ascertained using the scene recognition unit or using the AGC unit.

The scene-dependent parameterization of the AGC function is particularly suitable for mapping the scene dynamic range onto a certain specified output dynamic range in optimum fashion, that is to say for keeping the level of the output signal within a corresponding value range. For this purpose, in one suitable embodiment, an output dynamic range is specified having a lower end and an upper end. The parameters of the AGC function are then set such that they map the dynamic range, that is to say here the scene dynamic range, onto the output dynamic range. The lower end of the scene dynamic range is in particular mapped onto the lower end of the output dynamic range and the upper end of the scene dynamic range is in particular mapped onto the upper end of the output dynamic range. Between these, that is to say between the lower and upper end, linear mapping is in particular carried out. This achieves an optimum overlap of the scene dynamic range and the output dynamic range.

An embodiment in which the output dynamic range corresponds to a hearing range of the user is particularly advantageous. The AGC function is then adapted on a scene-dependent basis such that the scene dynamic range is mapped onto the hearing range in optimum fashion. The parameters of the AGC function are set such that the output dynamic range, which is ultimately output to the user, corresponds as far as possible to the hearing range, such that this hearing range overlaps with the scene dynamic range in optimum fashion and optimum use is made of the hearing capabilities of the user. In principle, it is already advantageous for the scene dynamic range to be mapped at least predominantly onto the hearing range, preferably to a degree of at least 90%. The hearing range is defined by the level values able to be perceived by the user. A signal having a level within the hearing range is audible to the user, but a signal having a level outside of this is not. The hearing range is accordingly individual and possibly different for each user. A signal the dynamic range of which lies at least partially outside the hearing range appears to be disturbed for the user and may be difficult for them to understand in some cases. Whether or not a level is audible is necessarily subjective. The hearing range is for example determined outside of the method described here by way of an appropriate hearing test. The hearing range is then stored appropriately in the hearing aid.

The corresponding AGC function for mapping the scene dynamic range onto the hearing range may in principle then be used in this way. In one advantageous embodiment, however, the AGC function is adapted further in addition, for example as an additional step following or during adaptation to the hearing range, by shifting the lower end or the upper end of the output dynamic range, that is to say by setting a difference between the lower end or upper end of the hearing range and the lower end, respectively upper end, of the output dynamic range, as described in further detail below. Although the output dynamic range then differs only slightly from the hearing range, it is thereby possible to reduce comb filter effects.

The lower and upper ends mentioned here are each level values (also volume values), which are for example given in dB. The hearing range and any dynamic ranges are accordingly each a level range (also volume range).

The explanations regarding the dynamic range apply analogously to the hearing range (also “hearing dynamic range”), with the difference that the hearing range is not based on an actual signal, but rather indicates a property of the user. Nevertheless, the hearing range has a lower end (minimum) and an upper end (maximum) and indicates a value range for a level. The upper and lower end of the hearing range may be determined and defined as described above for the dynamic range.

In one suitable embodiment, different scenes are distinguished “nominally” from one another, that is to say by way of a classifier, for example in the sense of “loud environment”, “quiet speech”, etc. As an alternative or in addition, different scenes are described by one or more parameters, for example noise level, SNR or dynamic range, with these parameters then preferably being used to control the dynamic range of the AGC unit. Delimiting different scenes by way of a classifier may be achieved appropriately in a variety of ways: for example with threshold values for the mentioned parameters (SNR etc.) or as a statistical classifier that statistically analyzes the parameters, the input signal or a modified form of the input signal and recognizes a respective scene based thereon. A trained classifier, for example a neural network or the like, is also suitable as a classifier. The voice activity recognition unit, mentioned further below, is also suitable as a classifier for classifying a scene. In the present case, the term “scene” preferably refers specifically to the respectively relevant dynamic range, which may be different on a frequency-specific basis and which is preferably orientated primarily at the dynamic range of a target speaker and is then also oriented, on a secondary basis, at the dynamic range of the acoustic scene (environment), that is to say ambient noise or the current noise level.

An individual AGC function fixedly specified for different scenes makes it possible at best to restrict mapping of the scene dynamic range onto the specified output dynamic range, specifically the hearing range of the user. In contrast thereto, according to the present invention, the AGC function is adapted as required. Usage acceptance of a hearing aid is thereby improved.

Expediently, the hearing range is a comfortable hearing range of the user. The comfortable hearing range is in particular defined by way of a conventional hearing test, in which for example the hearing threshold of the user is measured on a frequency-dependent basis by an audiologist, this hearing threshold constituting a lower level limit of perception, and additionally also an uncomfortableness threshold (UCL) as upper limit level. The comfortable hearing range lies between these two level limits. This may in principle also be defined in more detail with the aid of a test for the range of what is known as most comfortable loudness (MCL). As an alternative or in addition, the dynamic range of the current acoustic scene is a relevant dynamic range of this scene that is orientated in particular primarily at the dynamic range of a target speaker and expediently additionally also, on a secondary basis (for example in a scene without voice), at the dynamic range of the environment, that is to say ambient noise or the current noise level.

In one preferred embodiment, one of the parameters is a first knee point that is set such that it lies at the lower ends of the dynamic range (scene dynamic range) and of the output dynamic range, and another one of the parameters is a second knee point that is set such that it lies at the upper ends of the dynamic range and of the output dynamic range. The dynamic range and the output dynamic range are accordingly encompassed by the two knee points. The two knee points divide the AGC function into three, with a first section between the two knee points, a second section after the second knee point and a third section before the first knee point. Preferably, all three sections are straight, that is to say linear. The first section is the one most relevant to the user, since it preferably determines the gain of the AGC input signal in the hearing range. The second and third section then define the gain of the AGC input signal outside the hearing range. Setting the two knee points as described such that they mark the lower and upper ends means that the scene dynamic range is mapped exactly onto the output dynamic range, specifically the hearing range.

In one exemplary embodiment, the lower end of the output dynamic range is 40 dB and the upper end of the output dynamic range is 60 dB. In a first scene, the lower end of the dynamic range (scene dynamic range) is 20 dB and the upper end of the dynamic range is 80 dB. The gradient on the first section is then <1 and the dynamic range is compressed in this scene during operation, since it is greater than the output dynamic range. In another, second scene, the lower end of the dynamic range is then 60 dB and the upper end of the dynamic range is 70 dB. The gradient in the first section is then >1 and the dynamic range is expanded in this scene during operation, since it is then greater than the output dynamic range. While the dynamic range changes from scene to scene, the output dynamic range typically remains unchanged.

In a further preferred embodiment, one of the parameters is an offset (gain shift) that is set to a value that corresponds to a difference between the lower end of the output dynamic range, specifically the hearing range, and the dynamic range. In other words: the offset g_{shift} is given from the lower end Olow of the output dynamic range and the lower end d_{low} of the dynamic range according to

$${g}_{shift} = {o}_{low} - {d}_{l o w} .$$

Appropriately, the lower end of the output dynamic range is determined such that the difference from the lower end of the dynamic range does not exceed a maximum value. The offset is accordingly limited to a maximum value. Differences in the gain of different scenes are thereby maintained at least in terms of quality, which leads to more natural rendering of the scenes for the user. The lower end of the output dynamic range is accordingly possibly effectively shifted depending on the lower end of the scene dynamic range and the maximum value and then deviates accordingly from the originally specified lower end of the output dynamic range.

In a further preferred embodiment, one of the parameters is a first gradient that is set such that it corresponds to the ratio of a difference between the upper and lower end of the dynamic range, specifically the hearing range, to a difference between the upper and lower end of the dynamic range (scene dynamic range). The first gradient s_{hearing} is given from the upper end o_{high} and lower end o_{low} of the output dynamic range and the upper end d_{high} and lower end d_{low} of the dynamic range according to

$${s}_{hearing} = ( {o}_{high} - {o}_{low} ) / ( {d}_{high} - {d}_{low} ) .$$

The first gradient is accordingly in particular the gradient of the AGC function on the first section, already mentioned further above, between the two knee points. The first gradient also generally indicates the gain of the AGC unit for level values within the scene dynamic range. Depending on the size of the dynamic range in a given current acoustic scene and the size of the output dynamic range (specifically the individual hearing range), this then results in a gradient of <1, that is to say a compression, or of=1, that is to say simple forwarding, or of >1, that is to say an expansion. Optionally, the first gradient is limited to a maximum value in order to avoid possible artefacts. The maximum value is in particular >1.

It is expediently ascertained whether or not voice is present in the input signal, and the first gradient is limited to a value of 1 if no voice is present in the input signal. A voice activity detection unit is preferably used for ascertaining whether or not voice is present in the input signal. The voice activity detection unit is in particular part of the signal processor and obtains the input signal or a signal derived therefrom in order to ascertain whether or not voice is present in the input signal. The described limit of 1 in the case of the absence of voice limits expansion by the AGC unit to cases in which voice is present.

In a further preferred embodiment, one of the parameters is a second gradient that is set such that it corresponds to the ratio of a difference between a maximum hearing level and the upper end of the output dynamic range, specifically the hearing range, to a difference between a maximum scene level and the upper end of the dynamic range. The second gradient indicates in particular the gain of the AGC unit along the second section, that is to say above the second knee point. The second gradient s_{loud} is then given from the maximum hearing level hₘₐₓ, the upper end o_{high} of the output dynamic range, the maximum scene level dₘₐₓ and the upper end d_{high} of the dynamic range according to

$${S}_{loud} = ( {h}_{max} - {o}_{high} ) / ( {d}_{max} - {d}_{high} ) .$$

The maximum hearing level is greater than the upper end of the output dynamic range and in particular indicates an overall maximum permissible level for the output signal. The maximum hearing level is in particular what is known as the uncomfortableness threshold (UCL), which is either measured or approximated. By way of example, the maximum hearing level is 70 dB. The maximum scene level is in particular greater than the upper end of the dynamic range, for example the upper end has been determined based on a statistical analysis and the maximum scene level then corresponds to a measured absolute maximum of the level of the current acoustic scene. By way of example, the maximum scene level is 90 dB. The maximum scene level is for example defined as a highest signal level (on a frequency-specific basis) within a certain time period. If the AGC unit is adapted to this maximum scene level, this means in particular that this level and all levels below it are brought into the hearing range by the AGC unit. Levels above this (which are statistically less probable) would then appropriately fall into the working range of an additional algorithm, for example an output limiter or maximum power output limiter.

Preferably, the second gradient is limited to a value of at most 1, that is to say no expansion is permitted on the second section.

The scene-dependent adaptation of the AGC function according to the invention also makes it possible to reduce comb filter effects. A comb filter effect is an artefact that results from the output signal of the hearing aid being overlaid with a direct sound signal, direct sound for short. The direct sound then reaches the ear canal of the user while bypassing the hearing aid, for example via a vent or a dome of an earpiece of the hearing aid. On account of the processing in the hearing aid, a time offset is created between the output signal and the direct sound, and the output signal is typically delayed relative to the direct sound. A comb filter effect is most noticeable when the background noise in the scene is static, that is to say has only a slight variation, and when the direct sound and the output signal have a similarly high level. The level of the direct sound signal is also referred to as direct sound level. The comb filter effect is accordingly strongly dependent on the type and level of the input signal. Since the gain of the hearing aid is user-dependent and may be non-linear, the comb filter effects vary from hearing aid to hearing aid, since these are configured depending on the user (known as fitting/adaptation). It is accordingly difficult to provide a static solution to the comb filter problem.

It is possible in principle to deactivate frequency ranges that have a particularly high susceptibility to comb filter effects when fitting the hearing aid to the user. These frequency ranges are then however accordingly also excluded later from advantageous features such as interfering noise suppression and the like. This procedure also does not take into consideration the situation-dependent occurrence of comb filter effects, namely the non-linear relationship between direct sound level and level of the output signal output by the hearing aid. Another possible solution would accordingly be to predict a comb filter effect by way of the scene recognition unit and then to deactivate the potentially impacted frequency ranges on a situational basis. Such a prediction is difficult, however.

In the present case, therefore, the settable AGC function is advantageously used to avoid comb filter effects. In one suitable embodiment, the current acoustic scene is ascertained in accordance with the direct sound level and the one or more parameters of the AGC function are set such that the lower end or the upper end of the output dynamic range is at a specified minimum distance from the direct sound level. An optimum AGC function is thereby ascertained and set automatically for each acoustic scene, as a result of which the occurrence of a comb filter effect is then avoided. In this case, voice and ambient noise are maintained to the maximum extent, particularly when at the same time, as already described, the scene dynamic range is also mapped onto the hearing range in as optimum fashion as possible, but now taking into consideration potential comb filter effects. Use is made here of the finding that comb filter effects are most noticeable when the direct noise level is similar to the level of the output signal and when the current acoustic scene contains static interfering noise. In this situation, comb filter effects are particularly impactful and are therefore in particular avoided in such a situation in this case. It is assumed here that a static interfering noise (for example static background noise) represents the minimum, that is to say the lower end, of the scene dynamic range. This is also referred to as a noise floor. On the one hand, the static interfering noise then reaches the user as direct sound, and the direct sound level corresponds to the actual level of the static interfering noise. On the other hand, the interfering noise reaches the user via the hearing aid, and the lower end of the scene dynamic range and thus the static interfering noise is mapped onto the lower end of the specified output dynamic range, namely by way of the AGC function. A comb filter effect thus arises specifically when the direct sound level is similar to the lower end of the output dynamic range. The risk of comb filter effects is thus reduced by a corresponding minimum distance between the lower end of the output dynamic range and the direct sound level.

A description has been given above of the preferred application scenario where the direct sound level is a level of a static interfering noise in the acoustic scene and/or corresponds to a lower end of the dynamic range of the scene. However, the explanations also apply analogously to other direct sound signals and also analogously to the upper end of the output dynamic range, which may be shifted analogously in order to maintain a minimum distance from the direct sound level and thereby to avoid comb filter effects or another effect.

The minimum distance is appropriately at least 3 dB. The minimum distance is preferably at most 6 dB. The direction in which the minimum distance is maintained is of lesser importance. The corresponding end of the output dynamic range may in fact be shifted such that the direct sound level lies either within or outside the output dynamic range; all that is important is that the minimum distance is maintained. Expediently, the corresponding end of the output dynamic range is shifted in the direction in which the smaller change is required. If for example the direct sound level is 59 dB and the lower end of the output dynamic range is 60 dB, then the lower end is shifted up by at least 2 dB, better still 5 dB, for example to 62 dB, respectively 65 dB. If on the other hand the direct sound level is for example 46 dB and the lower end of the output dynamic range is 45 dB, then the lower end is by contrast shifted down by at least 2 dB, better still 5 dB, that is to say to 43 dB, respectively 40 dB.

The direct sound level may in principle be ascertained in various ways. Ascertaining the direct sound level is however in principle difficult and susceptible to errors. Therefore, in the present case, advantageously just the direct sound level is ascertained by measuring the lower end (minimum) of the dynamic range (scene dynamic range) and using it as direct sound level. Expediently, the direct sound level is a level of a static interfering noise in the acoustic scene, in which case the approximation is particularly justified. This method is particularly robust, and it is not necessary to deactivate individual frequency ranges. The concept described here is instead based in particular solely on the scene-dependent adaptation of the AGC function. The additional adaptation in order to avoid comb filter effects also advantageously takes place at the lower end of the scene dynamic range, that is to say at the interfering noise end of the acoustic scene, while the upper end, which is particularly relevant to voice output, appropriately remains uninfluenced by any correction in order to avoid comb filter effects. This reduces comb filter effects and at the same time voice intelligibility and noise quality are maintained to a maximum extent.

By way of example, the above concept is implemented by first checking whether the absolute difference between the lower end of the output dynamic range and the direct sound level corresponds to less than the minimum distance, for example as follows:

$$\vert {o}_{low} - {n}_{l o w} \vert < 6 dB ?$$

wherein n_{ow} is the direct sound level and it is assumed that n_{low}=d_{low}, that is to say the direct sound level is assumed to be static background noise at the lower end of the scene dynamic range. If it is then additionally the case that

$${n}_{l o w} \geq {o}_{low} ,$$

then it is written that

$${o}_{low} = {n}_{l o w} - 6 dB .$$

If, on the other hand, it is additionally the case that

$${n}_{l o w} < {o}_{low} ,$$

then it is written that

$${o}_{low} = {n}_{l o w} + 6 dB .$$

In one suitable embodiment, the parameters are set on a frequency-dependent basis. In other words, the AGC input signal or just the input signal is divided into multiple frequency ranges, for example by way of a filter bank, which is in particular part of the signal processor. The parameters are then set separately for each of the frequency ranges, such that a separate AGC function is used for each individual frequency range.

It is also advantageous to take into consideration the hearing effort (equivalent: exhaustion) of the user when setting the parameters. In one suitable embodiment, a hearing effort of the user is accordingly ascertained and one or more of the parameters are additionally set (that is to say in addition to the scene dependency) depending on the hearing effort. By way of example, the upper and/or lower end of the output dynamic range are modified in this case by way of a psychoacoustic model, such that the ends then possibly deviate from the originally specified values. It is thus advantageous for the upper end of the output dynamic range to be reduced, that is to say to be shifted toward a lower level value, if the hearing effort was large, that is to say exceeded a corresponding threshold value, during a certain previous time interval of for example 15 minutes. As an alternative or in addition, on the contrary, it is advantageous for the lower end of the output dynamic range to be increased, that is to say to be shifted toward a higher level value, if the hearing effort was small, that is to say fell below a corresponding threshold value, during a certain previous time interval of for example 15 minutes. The hearing effort is for example determined simply on the basis of the average level of the scene, it then being assumed that, in the case of an average level above a certain limit value, a high hearing effort is present and, on the contrary, in the case of an average level below a certain limit value, a low hearing effort is present.

Other features which are considered as characteristic for the invention are set forth in the appended claims.

Although the invention is illustrated and described herein as embodied in a hearing aid and method for operating a hearing aid, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a block diagram of a hearing aid;

FIG. 2 is a flow chart showing a method for operating the hearing aid from FIG. 1;

FIG. 3 is a graph showing an AGC function, parameterized for a first scene;

FIG. 4 is a graph showing the AGC function from FIG. 3, parameterized for a different, second scene;

FIG. 5A is a graph showing the AGC function from FIG. 3, parameterized for a third scene;

FIG. 5B is a graph showing the AGC function from FIG. 5A, additionally adapted to reduce comb filter effects;

FIG. 6A is a graph showing the AGC function from FIG. 3, parameterized for a fourth scene; and

FIG. 6B is a graph showing the AGC function from FIG. 6A, additionally adapted to reduce comb filter effects.

### DETAILED DESCRIPTION OF THE INVENTION

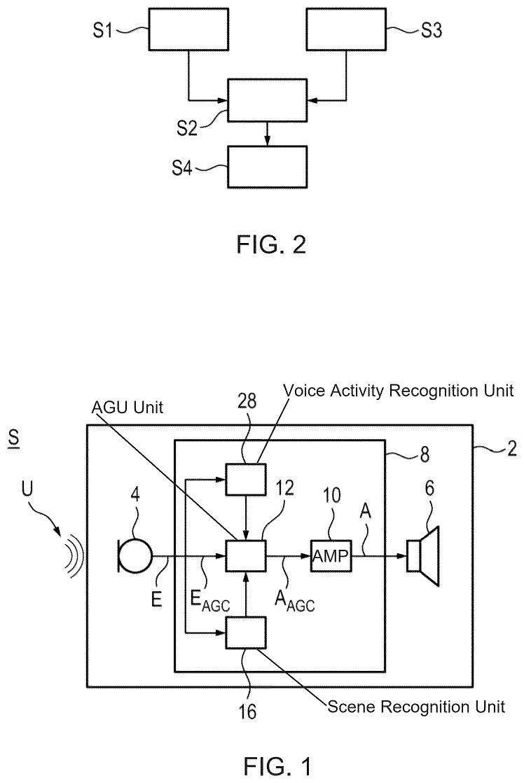

Referring now to the figures of the drawings in detail and first, particularly to FIG. 1 thereof, there is shown an exemplary embodiment of a hearing aid 2 that is assigned to a user who is not illustrated explicitly. The hearing aid 2 is assigned only to this user and is used only by the user. In the exemplary embodiment shown here, the hearing aid 2 is used to supply a user who is hard of hearing and to compensate for hearing loss of this user. During operation, the user wears and uses the hearing aid 2, for example on their head and in or on their ear.

The hearing aid 2 has an input transducer 4, here a microphone, an output transducer 6, here an earpiece, and a signal processor 8 (also referred to as signal processing unit). During operation, the input transducer 4 generates an input signal E, which is supplied to the signal processor 8. This modifies the input signal E and thereby ultimately generates an output signal A. In order to compensate for hearing loss, the input signal E or a signal derived therefrom is amplified by a frequency-dependent gain factor in accordance with an audiogram of the user, for example by an amplification unit 10. Lastly, the output signal A is output to the user by way of the output transducer 8.

FIG. 2 shows an exemplary method for operating the hearing aid 2. In step S1, the hearing aid 2 records an audio signal U by way of the input transducer 4, and generates the input signal E therefrom. An AGC input signal E_{AGC} is generated therefrom and is supplied to the AGC unit 12 of the hearing aid 2. In the simplest embodiment, the AGC input signal E_{AGC} is identical to the input signal E; as an alternative, only part of the input signal E is used as AGC input signal E_{AGC} or the input signal E is also modified beforehand by another unit of the signal processor 8 and then used as AGC input signal E_{AGC}. The AGC unit 12 is part of the signal processor 8 and is arranged upstream of, alternatively downstream of or in parallel with the amplification unit 10 in FIG. 1.

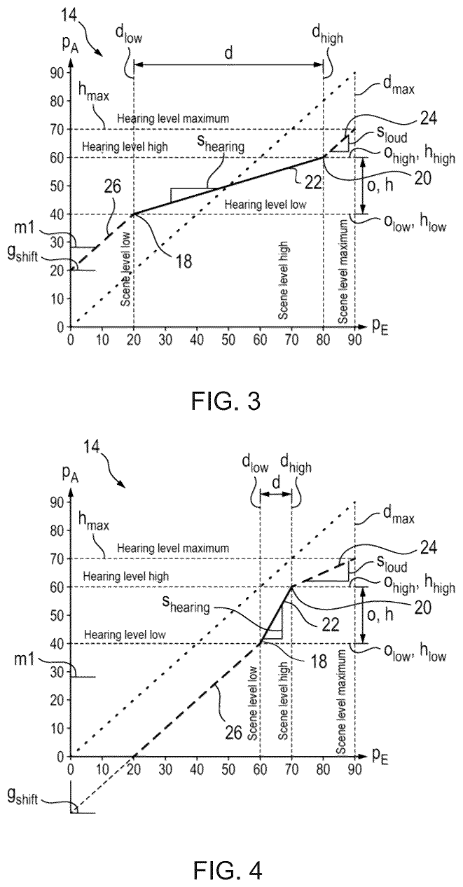

The AGC unit 12 amplifies the AGC input signal E_{AGC} depending on a level p_{E} of the AGC input signal E_{AGC} and in accordance with an AGC function 14 and then outputs the correspondingly amplified AGC input signal E_{AGC} as an AGC output signal A_{AGC}. Six exemplary embodiments of the AGC function 14 are shown in FIGS. 3 to 5B. The AGC function 14 assigns a level p_{A}, more precisely a level value of the output signal A or AGC output signal A_{AGC}, to each level p_{E}, more precisely each level value of the input signal E or AGC input signal E_{AGC}. The ratio between these two level values p_{E}, p_{A}gives rise to a gain that is applied by the AGC unit 12 for a corresponding level value of the AGC input signal E_{AGC} in order to amplify it. The gain may in principle be less than, greater than or equal to 1, that is to say an attenuation and compression (<1), simple forwarding (=1) or even an actual amplification and expansion (>1) may take place.

The AGC function 14 is defined by one or more parameters 18, 20, g_{shift}, s_{hearing}, s_{loud}, wherein multiple parameters P are assumed here, without restricting generality. The parameters define the form or the profile of the AGC function 14 and are therefore also referred to as AGC parameters. These parameters are settable in order to change the AGC function 14 and thus the modification of the AGC input signal E_{AGC} by the AGC unit 12. In the present case, in step S2, the parameters are set depending on an acoustic scene S that is currently present, that is to say depending on a current acoustic scene S. An acoustic scene S (just “scene” for short) is generally understood to mean an acoustic environment in which the user is potentially located. The current acoustic scene S is then the acoustic environment in which the user and thus also the hearing aid 2 are actually located at the present time. The acoustic environment and thus the scene S is defined by any sound signals, both useful noise and interfering noise, which may reach the user and the hearing aid 2 with a different intensity and/or from different directions, and also by any acoustic properties of the environment.

The acoustic scene S that is currently present is determined by way of a scene recognition unit 16 in step S3 in the exemplary embodiment shown here. The input signal E or a signal derived therefrom is supplied to the scene recognition unit 16, which then determines the scene S on the basis thereof. The AGC unit 12 is connected to the scene recognition unit 16 and is controlled thereby, that is to say the parameters are set automatically depending on the determination of the current acoustic scene S. The scene recognition unit 16 outputs a control signal that is dependent on the respective scene S and is received by the AGC unit 12 in order then to set the parameters on a scene-dependent basis.

Finally, in step S4, the hearing aid 2 generates an output signal A to be output to the user from the AGC output signal A_{AGC}. In the simplest embodiment, the output signal A is identical to the AGC output signal A_{AGC}. As an alternative, only part of the AGC output signal A_{AGC} is used as output signal A, or the AGC output signal A_{AGC}—as shown in FIG. 2—is also modified beforehand by another unit of the signal processor 8, for example the amplification unit 10, and then used as output signal A.

The AGC input signal E_{AGC} (and generally the input signal E) has an input dynamic range d, and the AGC output signal A_{AGC} (and generally the output signal A) has an output dynamic range o, and the AGC function 14 maps the input dynamic range d onto the output dynamic range o. The input dynamic range d and the output dynamic range o are generally also each referred to as a “dynamic range”. The term “dynamic range” signifies a metric for a value range covered by a changeable level of a signal (for example input signal E, output signal A, AGC input signal E_{AGC}, AGC output signal A_{AGC}). The term “lower end” is then understood to mean a minimum of the dynamic range d, and in the same way the term “upper end” is understood to mean a maximum. In one particularly simple embodiment, the lower and upper end d_{low}, d_{high} of the dynamic range d correspond to a minimum, respectively a maximum, of the level of the signal in question, for example the input signal E or the AGC input signal E_{AGC}. However, other definitions are also suitable as the upper and lower end d_{high}, d_{low} of the dynamic range d, for example based on a statistical analysis, such that the lower and upper end d_{low}, d_{high} of the dynamic range d of the current acoustic scene S are then ascertained based on a statistical analysis of the input signal E. In the same way, the output dynamic range o also has an upper end o_{high} and a lower end o_{low}.

In the present case, the AGC function 14 maps the dynamic range d onto the output dynamic range o. This is understood to mean that the lower end d_{low} of the dynamic range d is mapped onto the lower end o_{low} of the output dynamic range o and the upper end d_{high} of the dynamic range d is mapped onto the upper end o_{high} of the output dynamic range o. Between these, that is to say between the lower and upper end d_{low}, o_{low}, d_{high}, o_{high}, linear mapping is carried out. This achieves an optimum overlap of the scene dynamic range d and the output dynamic range o and in particular makes optimum use of the hearing capabilities of the user.

The current acoustic scene S has the dynamic range d that is ascertained, for example derived from the input signal E, for example either directly as a minimum and maximum of the input signal E or as a minimum and maximum of the AGC input signal E_{AGC}, which for its part is derived from the input signal E. The dynamic range d of the current acoustic scene S is also referred to as a scene dynamic range. The input dynamic range already mentioned or a dynamic range derived therefrom is particularly suitable as a dynamic range d of the current acoustic scene S. The ascertaining of the scene S and the dynamic range d thereof is part of the method described herein and takes place in step S2 or in step S3.

The scene-dependent parameterization of the AGC function 14 is suitable for mapping the scene dynamic range onto a certain specified output dynamic range o, that is to say for keeping the level p_{A} of the output signal A within a corresponding value range. An output dynamic range o is specified for this purpose. The parameters of the AGC function 14 are then set such that they map the dynamic range d, that is to say here the scene dynamic range, onto the output dynamic range o. In the present case, the lower end d_{low} of the scene dynamic range is mapped onto the lower end o_{low} of the output dynamic range o and the upper end d_{high} of the scene dynamic range is mapped onto the upper end o_{high} of the output dynamic range o. Linear mapping takes place between these. Overall, an optimum overlap between the scene dynamic range and the output dynamic range o is achieved.

FIGS. 3, 4, 5A and 6A show exemplary embodiments in which the output dynamic range o corresponds exactly to a hearing range h of the user. The AGC function 14 is adapted on a scene-dependent basis such that the scene dynamic range is mapped optimally onto this hearing range h. The parameters of the AGC function 14 are set such that the output dynamic range o, which is ultimately output to the user, corresponds as far as possible to the hearing range h, such that this hearing range h overlaps with the scene dynamic range in optimum fashion and optimum use is made of the hearing capabilities of the user. In principle, however, it is already advantageous for the scene dynamic range to be mapped at least predominantly onto the hearing range h, for example to a degree of at least 90%.

The hearing range h is defined by the level values able to be perceived by the user. A signal having a level within the hearing range h is audible to the user, but a signal having a level outside of this is not. The hearing range h is accordingly individual and possibly different for each user. A signal the dynamic range of which lies at least partially outside the hearing range h appears to be disturbed for the user and may be difficult for them to understand.

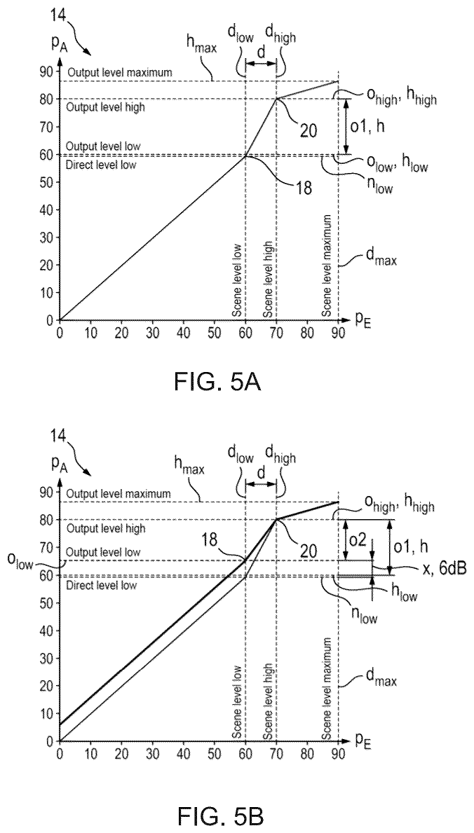

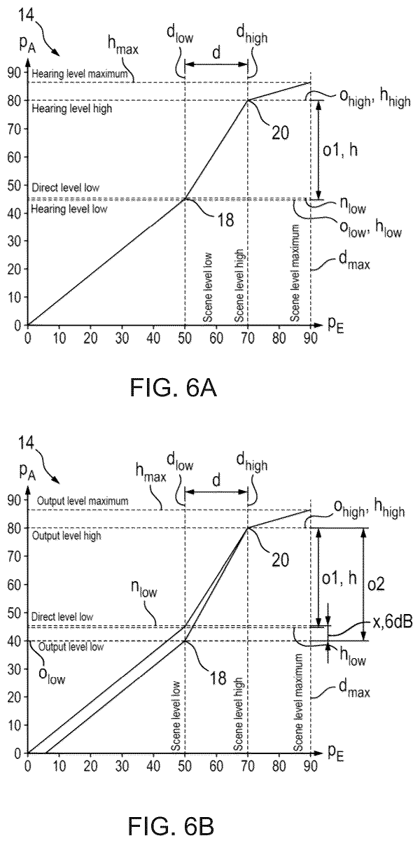

The hearing range h is for example determined outside of the method described here by way of an appropriate hearing test. In the present case, the hearing range h is stored in the hearing aid 2. Two exemplary embodiments in which the output dynamic range o corresponds to the hearing range h, such that the scene dynamic range is effectively mapped onto the hearing range h, are illustrated for two different scenes S in FIGS. 3 and 4. FIGS. 5A and 6A each also show an exemplary embodiment in which the scene dynamic range is effectively mapped onto the hearing range h. Since, however, in these two scenes S, there is the risk of comb filter effects, the AGC function 14 is additionally also adapted here in order to achieve a slightly changed output dynamic range o in order to reduce comb filter effects. The result of this is shown in FIGS. 5B and 6B. In FIGS. 5B and 6B, as an additional step after or during the adaptation to the hearing range h, the AGC function 14 is thus adapted further by in this case specifically shifting in each case the lower end o_{low} (alternatively or additionally the upper end o_{high}) of the output dynamic range o, that is to say a difference between the lower end h_{low}of the hearing range h and the lower end o_{low} of the output dynamic range o is set. This is described in more detail below. Although the output dynamic range o then differs slightly from the hearing range h, it is thereby possible to reduce comb filter effects.

The explanations regarding the dynamic range apply analogously to the hearing range h, with the difference that the hearing range h is not based on an actual signal, but rather indicates a property of the user. Nevertheless, the hearing range h has a lower end h_{low}(minimum) and an upper end h_{high} (maximum) and indicates a value range for a level. In the mapping of the scene dynamic range d onto the hearing range h, the parameters of the AGC function 14 are set such that a dynamic range d of the output signal A that is actually output to the user corresponds to the hearing range h, such that it overlaps the scene dynamic range d in optimum fashion.

The AGC function 14 and thus the behavior of the AGC unit 12 are then changed slightly here when the scene S also changes, that is to say when the scene recognition unit 16 is used to detect a change in the current acoustic scene S. Within the same scene S, on the other hand, the same AGC function 14 is used continuously, but is optimized to the scene S by the scene-dependent setting of the parameters. Setting the parameters depending on the current acoustic scene S means that the AGC function 14 is adapted to the scene S. This may even lead to an expansion (gain>1), in which case the SNR of the current acoustic scene S is then increased accordingly, while the dynamic range of the output signal A however continues to be limited to the hearing range h of the user.

In the embodiment shown here, one of the parameters is a first knee point 18 that is set such that it lies at the lower ends d_{low}, h_{low}of the dynamic range d and of the output dynamic range o, and another one of the parameters is a second knee point 20 that is set such that it lies at the upper ends d_{high}, h_{high} of the dynamic range d and of the output dynamic range o. This may be seen in FIGS. 3 and 4. The dynamic range d and the hearing range h are accordingly encompassed by the two knee points 18, 20. The two knee points 18, 20 divide the AGC function 14 into three, with a first section 22 between the two knee points 18, 20, a second section 24 after the second knee point 20 and a third section 26 before the first knee point 18. All three sections 22, 24, 26 are straight, that is to say linear. The first section 22 is the one most relevant to the user, since it determines the gain of the AGC input signal E_{AGC} in the output dynamic range o. The second and third section 24, 26 then define the gain of the AGC input signal E_{AGC} outside the output dynamic range o. The described setting of the two knee points 18, 20 such that they mark the lower and upper ends d_{low}, hlow, d_{high}, h_{high} maps the scene dynamic range d exactly onto the hearing range h in FIGS. 3, 4, 5A and 6A.

In FIGS. 3 and 4, the lower end how of the hearing range h is for example 40 dB and the upper end h_{high} is 60 dB. The output dynamic range o is identical to the hearing range h. In FIG. 3, the AGC function 14 is then shown for example in a first scene S in which the lower end d_{low} of the dynamic range d is 20 dB and the upper end d_{high} is 80 dB. The gradient on the first section 22 is then <1 and, during operation, the dynamic range d is compressed in this scene S, since it is greater than the output dynamic range o and the hearing range h. FIG. 4 then shows for example the AGC function 14 in a different, second scene S, in which the lower end d_{low} of the dynamic range d is 60 dB and the upper end d_{high} is 70 dB. The gradient on the first section 22 is then >1 and, during operation, the dynamic range d is expanded in this scene S, since it is then greater than the output dynamic range o and the hearing range h. While the dynamic range d changes from scene S to scene S, the output dynamic range o and the hearing range h remain unchanged.

In the present case, one of the parameters is an offset g_{shift} that is set to a value that corresponds to a difference between the lower ends hlow, d_{low} of the output dynamic range o and of the dynamic range d. By way of example, the lower end o_{low} of the output dynamic range o is determined such that the difference from the lower end d_{low} of the dynamic range d does not exceed a maximum value m1.

Furthermore, in the present case, another one of the parameters is a first gradient s_{hearing} that is set such that it corresponds to the ratio of a difference between the upper and lower end o_{high}, o_{low} of the output dynamic range o to a difference between the upper and lower end d_{high}, d_{low} of the dynamic range d. The first gradient s_{hearing} is accordingly the gradient of the AGC function 14 on the first section 22, which quite generally indicates the gain of the AGC unit 12 for level values within the scene dynamic range d. Depending on the size of the dynamic range d in a given current acoustic scene S and the size of the dynamic range o and specifically of the individual hearing range h, this then results in a gradient s_{hearing} of <1, that is to say a compression as in FIG. 3, of =1, that is to say simple forwarding, or of >1, that is to say an expansion as in FIG. 4. Optionally, the first gradient s_{hearing} is limited to a maximum value.

In the exemplary embodiment shown here, it is additionally ascertained whether or not voice is present in the input signal E, and the first gradient s_{hearing} is limited to a value of 1 if no voice is present in the input signal E. A voice activity detection unit 28 is used to ascertain whether or not voice is present in the input signal E.

Furthermore, in the present case, one of the parameters is a second gradient s_{loud} that is set such that it corresponds to the ratio of a difference between a maximum hearing level hₘₐₓ and the upper end o_{high} of the output dynamic range o to a difference between a maximum scene level dₘₐₓ and the upper end d_{high} of the dynamic range d. The second gradient s_{loud} indicates the gain of the AGC unit 12 along the second section 24. In FIGS. 3 and 4, the maximum hearing level hₘₐₓ is 70 dB and the maximum scene level dₘₐₓ is 90 dB.

Optionally, the second gradient s_{loud} is limited to a value of at most 1, that is to say no expansion is permitted on the second section 24.

The scene-dependent adaptation of the AGC function 14 also makes it possible to reduce comb filter effects, which is explained in more detail below with reference to FIGS. 5A, 5B, 6A and 6B. In this case, FIGS. 5A and 5B show a canteen scene, and FIGS. 6A and 6B show a highway scene. A comb filter effect is an artefact that results from the output signal A being overlaid with a direct sound signal, direct signal for short. A comb filter effect is most noticeable when the background noise in the scene S is static, that is to say has only a slight variation, and when the direct sound and the output signal A have a similarly high level. The level n_{low} of the direct sound signal is also referred to as direct sound signal niow.

In the present case, the settable AGC function 14 is used to avoid comb filter effects. For this purpose, the direct sound level n_{low} of the current acoustic scene S is first ascertained and the one or more parameters of the AGC function 14 are set such that the lower end o_{low} or the upper end o_{high} of the output dynamic range o is at a specified minimum distance x from the direct sound level n_{low}. An optimum AGC function 14 is thereby ascertained and set automatically for each acoustic scene S, as a result of which the occurrence of a comb filter effect is then avoided. In this case, voice and ambient noise are maintained to the maximum extent, particularly when at the same time, as also already described, the scene dynamic range is mapped onto the hearing range h in as optimum fashion as possible, but now taking into consideration potential comb filter effects. Use is made here of the finding that comb filter effects are most noticeable when the direct sound level n_{low} is similar to the level p_{A} of the output signal o and when the current acoustic scene S contains static interfering noise. Specifically, therefore, it is assumed here that static interfering noise (for example static background noise) forms the minimum, that is to say the lower end d_{low}, of the scene dynamic range. This is also referred to as a noise floor. On the one hand, the static interfering noise then reaches the user as direct sound, and the direct sound level n_{low} corresponds to the actual level of the static interfering noise. On the other hand, the interfering noise reaches the user via the hearing aid 2, and the lower end d_{low} of the scene dynamic range and thus the static interfering noise is mapped onto the lower end o_{low} of the specified output dynamic range o, here the hearing range h, by way of the AGC function 14, as shown in FIGS. 5A and 6A. A comb filter effect thus arises specifically when the direct sound level n_{low} is similar to the lower end o_{low} of the output dynamic range o, as shown in FIGS. 5A and 6A. The risk of comb filter effects is reduced by a corresponding minimum distance x between the lower end o_{low} of the output dynamic range o and the direct sound level n_{low}, as shown in FIGS. 5B and 6B.

In the exemplary embodiments shown here, the direct sound level n_{low} is a level of a static interfering noise in the acoustic scene S and corresponds to the lower end d_{low} of the dynamic range d of the scene S. However, the explanations also apply analogously to other direct sound signals and also analogously to the upper end o_{high} of the output dynamic range o, which may be shifted analogously in order to maintain a minimum distance x from the direct sound level (then n_{high}, not shown in the figures) and thereby to avoid comb filter effects.

The minimum distance x in this case is 6 dB. The direction in which the minimum distance x is maintained is of lesser importance; both variants are shown in FIGS. 5B and 6B. The lower end o_{low} may in fact be shifted such that the direct sound level n_{low} lies either within (FIG. 6B) or outside (FIG. 5B) the output dynamic range o; all that is important is that the minimum distance x is maintained. In the present case, the lower end o_{low} of the output dynamic range o is shifted in the direction in which the smaller change is required. For instance, if, in FIG. 5B, the direct sound level n_{low} is 59 dB and the lower end o_{low} of the output dynamic range o is 60 dB, then the lower end o_{low} is shifted up by 5 dB, that is to say to 65 dB. If on the other hand the direct sound level nlow, as shown in FIG. 6B, is 46 dB and the lower end o_{low} of the output dynamic range o is 45 dB, then, conversely, the lower end o_{low} is shifted down by 5 dB, that is to say to 40 dB. The respective shift is achieved here by shifting the first knee point 18. This also results in a different gradient on the first section 22. In principle, however, other adaptations of the AGC function 14 are also conceivable in order to shift the lower end o_{low} accordingly and to produce the minimum distance x. In FIGS. 5A to 6B, the dynamic range o corresponding only exactly to the hearing range h has been designated o1, and the output dynamic range o shifted in order to reduce comb filter effects has been designated o2.

The direct sound level n_{low} may in principle be ascertained in various ways. In the present case, the direct sound level n_{low} is ascertained simply by measuring the lower end d_{low} of the dynamic range d and using it as a direct sound level n_{low}. This is possible since the direct sound level n_{low} is a level of a static interfering noise in the acoustic scene S.

The additional adaptation, shown in FIGS. 5B and 6B, in order to avoid comb filter effects is carried out at the lower end d_{low} of the scene dynamic range, that is to say at the interfering noise end of the acoustic scene S, while the upper end d_{high}, which is particularly relevant to voice output, remains uninfluenced by any correction in order to avoid comb filter effects. This reduces comb filter effects and at the same time voice intelligibility and noise quality are maintained to a maximum extent.

The above concept is implemented here by first checking whether the absolute difference between the lower end o_{low} of the output dynamic range o and the direct sound level n_{low} corresponds to less than the minimum distance x, that is to say whether the following is satisfied:

$$\vert {o}_{low} - {n}_{l o w} \vert < 6 dB ?$$

It is assumed here that n_{low}=d_{low}, that is to say the direct sound level n_{low} is assumed to be static background noise at the lower end d_{low} of the scene dynamic range. If it is then additionally the case that

$${n}_{l o w} \geq {o}_{low} ,$$

as shown in FIG. 6A, then it is written that

$${o}_{low} = {n}_{l o w} - 6 dB ,$$

as shown in FIG. 6B. If, on the other hand, it is additionally the case that

$${n}_{l o w} < {o}_{low} ,$$

as shown in FIG. 5A, then it is written that

$${o}_{low} = {n}_{l o w} + 6 dB ,$$

as shown in FIG. 5B.

In one embodiment that is not shown explicitly, the parameters are set on a frequency-dependent basis. In other words: the AGC input signal E_{AGC} or just the input signal E is divided into multiple frequency ranges, for example by way of a filter bank, which is for example part of the signal processor 8. The parameters are then set separately for each of the frequency ranges, such that a separate AGC function 14 is used for each individual frequency range.

It is likewise also optional to take into consideration the hearing effort (equivalent: exhaustion) of the user when setting the parameters. In one suitable embodiment, a hearing effort of the user is accordingly ascertained and one or more of the parameters are additionally set (in addition to the scene dependency) depending on the hearing effort.

The following is a summary list of reference numerals and the corresponding structure used in the above description of the invention:
2 hearing aid
4 input transducer
6 output transducer
8 signal processor
10 amplification unit
12 AGC unit
14 AGC function
16 scene recognition unit
18 first knee point
20 second knee point
22 first section
24 second section
26 third section
28 voice activity recognition unit
A output signal
A_{AGC} AGC output signal
d dynamic range of a scene, scene dynamic range
d_{low} lower end of the dynamic range of a scene
d_{high} upper end of the dynamic range of a scene
dₘₐₓ maximum scene level
E input signal
E_{AGC} AGC input signal
g_{shift} offset
h hearing range
h_{low}lower end of the hearing range
h_{high} upper end of the hearing range
hₘₐₓ maximum hearing level
m1 maximum value (for the offset)
n_{low} direct sound level
o, o1, o2 output dynamic range (for example dynamic range of the output signal or of the AGC output signal)
o_{low} lower end of the output dynamic range
o_{high} upper end of the output dynamic range
p_{A} level of the output signal/AGC output signal
p_{E} level of the input signal/AGC input signal
S scene
S1-S4 step
s_{hearing} first gradient
s_{loud} second gradient
U audio signal
X minimum distance

1. A method for operating a hearing aid being assigned to a user, which comprises the steps of:
recording an audio signal via the hearing aid;
generating an input signal from the audio signal;
generating an automatic gain control (AGC) input signal from the input signal and supplying the AGC input signal to an AGC unit of the hearing aid;
amplifying, via the AGC unit, the AGC input signal depending on a level of the AGC input signal and in accordance with an AGC function and then outputting an amplified AGC input signal as an AGC output signal, wherein the AGC function is defined by at least one parameter that is set in dependence on an acoustic scene that is currently present; and
generating, via the hearing aid, an output signal for outputting to the user and derived from the AGC output signal.

2. The method according to claim 1, wherein:
an output dynamic range is specified and has a lower end and an upper end;
a dynamic range of the acoustic scene is ascertained and has a lower end and an upper end; and
the at least one parament is one of a plurality of parameters and the parameters are set such that the AGC function maps the dynamic range onto the output dynamic range.

3. The method according to claim 2, wherein the output dynamic range corresponds to a hearing range of the user.

4. The method according to claim 3, wherein:
the hearing range is a comfortable hearing range of the user; and
the dynamic range is a relevant dynamic range.

5. The method according to claim 2, wherein:
one of the parameters is a first knee point that is set such that the first knee point lies at the lower ends of the dynamic range and of the output dynamic range; and
another one of the parameters is a second knee point that is set such that the second knee point lies at the upper ends of the dynamic range and of the output dynamic range.

6. The method according to claim 5, wherein one of the parameters is an offset, the offset is set to a value that corresponds to a difference between the lower ends of the output dynamic range and of the dynamic range.

7. The method according to claim 6, wherein the lower end of the output dynamic range is determined such that a difference from the lower end of the dynamic range does not exceed a maximum value.

8. The method according to claim 2, wherein one of the parameters is a first gradient that is set such that the first gradient corresponds to a ratio of a difference between the upper and lower end of the output dynamic range to a difference between the upper and lower end of the dynamic range.

9. The method according to claim 8, which further comprises:
ascertaining whether or not voice is present in the input signal; and
limiting the first gradient to a value of 1 if no said voice is present in the input signal.

10. The method according to claim 2, wherein one of the parameters is a second gradient that is set such that the second gradient corresponds to a ratio of a difference between a maximum hearing level and the upper end of the output dynamic range to a difference between a maximum scene level and the upper end of the dynamic range.

11. The method according to claim 10, wherein the second gradient is limited to a value of at most 1.

12. The method according to claim 2, wherein the lower end and the upper end of the dynamic range are ascertained as a minimum and maximum of the input signal within a predefined time range.

13. The method according to claim 2, which further comprises ascertaining the lower end and the upper end of the dynamic range based on a statistical analysis of the input signal.

14. The method according to claim 2, which further comprises:
ascertaining a direct sound level of the acoustic scene; and
setting at least one of the parameters such that the lower end or the upper end of the output dynamic range is at a predefined minimum distance from a direct sound level.

15. The method according to claim 14, which further comprises ascertaining the direct sound level by measuring the lower end of the dynamic range and using it as the direct sound level.

16. The method according to claim 14, wherein the predefined minimum distance is at least 3 dB.

17. The method according to claim 14, wherein the hearing aid has an ear canal microphone that is used to measure the direct sound level.

18. The method according to claim 2, wherein the parameters are set on a frequency-dependent basis.

19. The method according to claim 1, which further comprises:
ascertaining a hearing effort of the user; and
setting at least one of the parameters in dependence on the hearing effort.

20. A hearing aid, comprising:
a processor configured to perform the method according to claim 1.
